(19) United States
(12) Patent Application Publication
(10) Pub. No.: US 2022/0049345 A1
(43) Pub. Date: Feb. 17, 2022

(54) FLUORINE-DOPED OPTICAL MATERIALS FOR OPTICAL COMPONENTS

(71) Applicant: KLA CORPORATION, Milpitas, CA (US)

(72) Inventors: Gildardo Delgado, Livermore, CA (US); Vera (Guorong) Zhuang, San Jose, CA (US); John Savee, San Francisco, CA (US); Evgeniia Butaeva, San Jose, CA (US); Gary V. Lopez Lopez, Sunnyvale, CA (US); Grace Chen, Los Gatos, CA (US)

(21) Appl. No.: 17/393,953

(22) Filed: Aug. 4, 2021

Related U.S. Application Data
(60) Provisional application No. 63/066,333, filed on Aug. 17, 2020.

(51) Int. Cl. C23C 14/30; C23C 14/02; C23C 14/06

(52) U.S. Cl. CPC C23C 14/30; C23C 14/06; C23C 14/022

(57) ABSTRACT

An optical component includes an optical material which is a fluorine (F)-containing optical material doped with an F-containing species different from the F-containing optical material. A coating system for depositing the optical material onto a substrate or a bulk material of an optical component is an electron beam evaporation coating system, an ion assisted deposition coating system, or an ion beam sputtering coating system.

### CROSS REFERENCE TO RELATED APPLICATIONS

This Application claims priority to U.S. Provisional Patent Application 63/066,333, filed Aug. 17, 2020, the content of which is hereby incorporated by reference in its entirety.

### TECHNICAL FIELD

The present disclosure relates to optical components, more specifically, fluorine (F)-containing optical materials for the optical components, and coating systems for depositing the optical materials onto the optical components.

### BACKGROUND

F-containing optical materials are commonly used for broadband optical applications and/or systems, ranging from vacuum ultra-violet (VUV) to near-infrared (NIR) optical applications and/or systems. The performance of the F-containing optical materials can be rapidly degraded in VUV and deep ultra-violet (DUV) spectral ranges due to defects in the optical materials. These defects are found to be severely detrimental to the optical performance and lifetime of the optical applications and/or systems.

### SUMMARY

According to one embodiment, an optical component is disclosed. The optical component may include an optical material having a fluorine (F)-containing optical material doped with an F-containing species different from the F-containing optical material.

According to another embodiment, a coating system for depositing an optical material onto at least one sample is disclosed. The at least one sample may be a substrate or a bulk material of an optical component. The coating system may include a vacuum chamber. The coating system may further include a substrate holder positioned at a first location within the vacuum chamber. The substrate holder may have at least one recess to support the at least one sample. The coating system may also include a rotating axis supporting the substrate holder and configured to rotate the substrate holder as the optical material is deposited onto the at least one sample. The coating system may further include a container positioned at a second location within the vacuum chamber. The container may contain a target material to be deposited as the optical material onto the at least one sample. The target material may include an F-containing optical material. The coating system may also include an electron gun positioned adjacent to the container and configured to generate an electron beam. The electron beam may be directed to the target material to melt and evaporate the target material in a gaseous form which is then condensed as the optical material onto the at least one sample. The coating system may further include an inlet disposed on the vacuum chamber and through which an F-containing species is introduced into the vacuum chamber. The F-containing species may be mixed with the target material in the gaseous form and deposited onto the at least one sample with the target material in the gaseous form.

According to yet another embodiment, a coating system for depositing an optical material onto at least one sample is disclosed. The at least one sample may be a substrate or a bulk material of an optical component. The coating system may include a vacuum chamber. The coating system may further include a substrate holder positioned at a first location within the vacuum chamber. The substrate holder may have at least one recess to support the at least one sample. The coating system may also include a rotating axis supporting the substrate holder and configured to rotate the substrate holder as the optical material is deposited onto the at least one sample. The coating system may further include a container positioned at a second location within the vacuum chamber. The container may contain a target material to be deposited as the optical material onto the at least one sample. The target material may include an F-containing optical material. The coating system may also include an ion beam generator positioned adjacent to the container and configured to rotate in a first direction to direct to the at least one sample and to generate a first ion beam containing inert gas ions to clean the at least one sample. The ion beam generator may also be configured to rotate in a second direction to direct to the target material in the container during deposition and to generate a second ion beam containing fluorine ions to sputter the target material for depositing the target material onto the at least one sample. The coating system may further include an inlet disposed on the vacuum chamber and through which an F-containing species is introduced into the vacuum chamber. The F-containing species may be mixed with the target material and deposited onto the at least one sample with the target material.

### BRIEF DESCRIPTION OF THE DRAWINGS

FIG. 1 depicts a schematic diagram of a coating system according to a first embodiment of the present disclosure.

FIG. 2 depicts a schematic diagram of a coating system according to a second embodiment of the present disclosure.

FIG. 3 depicts a schematic diagram of a coating system according to a third embodiment of the present disclosure.

FIG. 4 depicts a schematic diagram of a coating system according to a fourth embodiment of the present disclosure.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

An optical component may include a substrate having an optical surface and a film layer formed on the optical surface, and a protective layer may be deposited on the film layer to protect the optical component from optical damage. Alternatively, an optical component may include a bulk material, and a protective layer may be deposited onto the bulk material to protect the optical component from optical damage. The optical damage may be caused by vacuum ultra-violet (VUV) and/or deep ultra-violet (DUV) radiation. VUV radiation generally refers to UV light with a wavelength in a range of 120 to 190 nm. DUV radiation generally refers to UV light with a wavelength in a range of 190 to 280 nm. Either the film layer or the bulk material may include an optical material which contains fluorine (F), also referred to as an F-containing optical material. Unfortunately, the F-containing optical material may be damaged by humidity, oxidation, contamination, radiation, and other environmental conditions. Specifically, when the optical component operates under an operation environment (e.g., vacuum containing residual gas or inert atmosphere containing impurities) upon VUV and/or DUV radiation, the F-containing optical material is susceptible to VUV and/or DUV radiation damage, which consequently deteriorates the optical performance of the optical component and shortens the lifetime of the optical component.

Upon absorption of VUV and/or DUV radiation, fluorine (F) atoms in the F-containing optical material may migrate from their original locations in the F-containing optical material. Some of these F atoms may leave the F-containing optical material. The migration and/or loss of the F atoms create defects, such as fluorian vacancy or interstitial F, in the F-containing optical material. The defects may be surface defects or bulk defects. Either the surface or bulk defects may negatively impact the optical performance of the optical component. For example, the migration and/or loss of the F atoms may induce either surface or subsurface oxidation of the F-containing optical material, and may also cause oxidation of the film layer when the film layer is deposited onto the optical component. Such oxidations may lead to degradation of the optical performance of the optical component over time. Computational calculations based on the Density Function Theory (DFT) also suggest that it is energetically favorable for oxygen to occupy the fluorian vacancy, which can lead to degradation to the optical performance of the optical component.

Optical components, including those applied in VUV and DUV optical applications and/or systems, are expected to have a long durable lifetime, such as ten years or longer. However, due to various detrimental optical damages, replacement of a damaged optical component is often required. Such a replacement can be expensive. A single layer of a silicon oxide (SiO₂) material doped with F has been developed to protect crystal surface materials that include metal fluorides, such as calcium fluoride (CaF₂). The F-doped SiO₂ material can help prevent surface damage of the CaF₂ crystal material when subjecting the CaF₂-containing crystal surface material to optical radiation at a wavelength of 193 nm. However, because SiO₂ can absorb radiation in VUV range (i.e., generally between 120 nm to 190 nm), SiO₂ is not ideal to be used as a coating material to protect F-containing optical materials that are often used in VUV and DUV optical applications and/or systems from VUV and/or DUV radiation damage. Therefore, there is a need for an optical material that is resistant to VUV and/or DUV radiation damage.

Aspects of the present disclosure relate to F-doped optical materials for optical components and coating systems for depositing the optical materials onto the optical components. In one embodiment, the present disclosure is directed to an optical component that includes an F-containing optical material doped with an F-containing species different from the F-containing optical material. In another embodiment, the present disclosure is directed to a coating system for depositing an F-containing optical material doped with an F-containing species onto an optical component, where the coating system may be an electron beam evaporation coating system. In yet another embodiment, the present disclosure is directed to a coating system for depositing an F-containing optical material doped with an F-containing species onto an optical component, where the coating system may be an ion assisted deposition (IAD) coating system or ion beam sputtering (IBS) coating system.

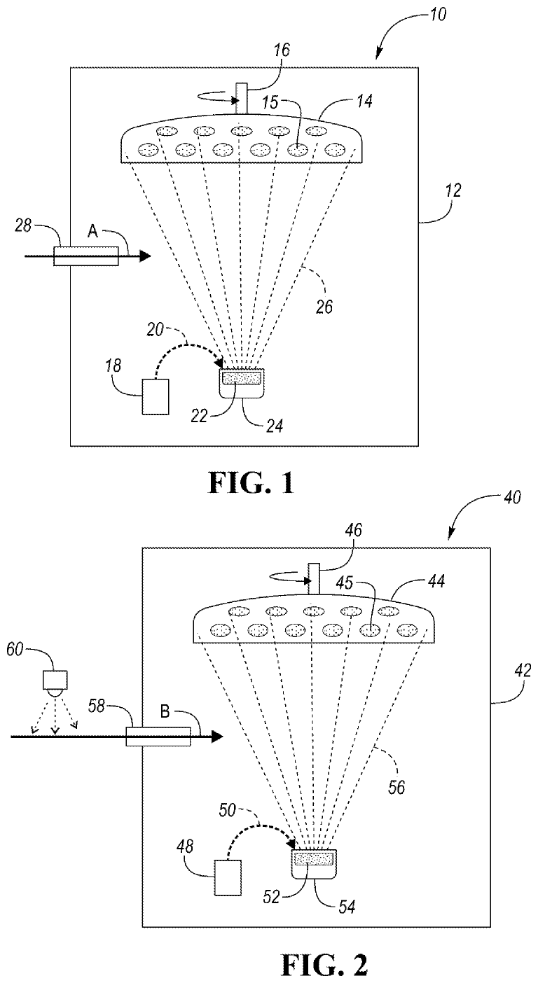

FIG. 1 depicts a schematic diagram of a coating system 10 according to a first embodiment of the present disclosure. In some embodiments, the coating system 10 may be used to deposit a first material onto a substrate to form an optical component. The first material may be deposited as a film layer onto the substrate. Thereafter, the coating system 10 may be used to deposit a second material onto the optical component. The second material may be deposited as a protective layer onto the optical component to protect the optical component from optical damage. The first and/or the second material may include an optical material, such as an F-containing optical material. The optical damage may be caused by VUV and/or DUV radiation. The optical component may be, but is not limited to, optical windows, beam splitters, mirrors, charge-coupled devices (CCDs), detectors, or time delay integration (TDI) CCDs. In some other embodiments, the coating system 10 may be used to deposit a material onto a bulk material of an optical component. The material may be deposited as a protective layer onto the optical component to protect the optical component from optical damage. The material may include an optical material, such as an F-containing optical material. The optical damage may be caused by VUV and/or DUV radiation. The optical component may be, but is not limited to, optical windows, beam splitters, mirrors, CCDs, detectors, or TDI CCDs.

The coating system 10 may be an electron beam (or e-beam) evaporation coating system. Electron beam evaporation is a form of physical vapor deposition taking place in a vacuum chamber, where a target material to be deposited onto a surface is first bombarded with an electron beam, followed by being melted, evaporated and transformed into a gaseous form. The gaseous atoms and/or molecules of the target material can be condensed onto the surface. The surface may be a surface of a substrate or a surface of a bulk material.

Referring to FIG. 1, the coating system 10 may include a vacuum chamber 12. The coating system 10 may further include a substrate holder 14 positioned at a first location within the vacuum chamber 12. The substrate holder 14 may include at least one recess 15. Each of the at least one recess 15 may support a sample thereon. The sample may be a substrate or a bulk material of an optical component. As such, at least one sample may be supported on the substrate holder 14 for deposition. The substrate holder 14 may also have a heating and temperature measurement capability, allowing a target material to be deposited onto the at least one sample at a specific temperature.

The coating system 10 may further include a rotating axis 16 which supports the substrate holder 14. The rotating axis 16 may include a motor (not shown) with configurable rotation speeds and configured to rotate the substrate holder 14 as the deposition of the target material takes place. The rotation of the substrate holder 14 during deposition may help achieve a uniform deposition of the target material on the at least one sample supported on the substrate holder 14.

The coating system 10 may further include an electron gun 18 configured to generate an electron beam 20 carrying high-energy electrons. The electron beam 20 may be directed to a target material 22 contained in a container 24. The container 24 is positioned at a second location within the vacuum chamber 12, for example, adjacent to the electron gun 18. The target material 22 may be an optical material to be deposited onto the at least one sample supported on the substrate holder 14. Upon being bombarded by the electron beam 20, the target material 22 may be melted, evaporated and transformed into a gaseous form 26. The gaseous atoms and/or molecules 26 of the target material 22 may then be condensed onto the at least one sample. A thickness of the deposited target material onto the at least one sample may be in a range of 1 nm to 1 μm. The target material 22 may be an F-containing optical material, including, but not limited to, magnesium fluoride (MgF₂), lanthanum fluoride (LaF₂), lithium fluoride (LiF), barium fluoride (BaF₂), aluminum fluoride (AlF₃), gadolinium fluoride (GdF₃), lutetium fluoride (LuF₃), or a combination thereof.

In some embodiments, when the at least one sample are substrates, a first target material may be deposited onto the substrates to form optical components. The first target material may be deposited as film layers onto the substrates. Thereafter, a second target material may be deposited onto the optical components. The second target material may be deposited as protective layers onto the optical components to protect the optical components from optical damage. The first and/or the second material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the first and second target materials deposited onto the at least one sample may be in a range of 1 nm to 1 μm.

In some other embodiments, when the at least one sample are bulk materials of optical components, a target material may be deposited onto the bulk materials of the optical components. The target material may be deposited as protective layers onto the optical components to protect the optical components from optical damage. The target material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the target material deposited onto the at least one sample may be in a range of 1 nm to 1 μm.

To further protect the deposited optical material from radiation damage, especially VUV and/or DUV radiation damage, the target material 22 may be doped with an additional fluorine (F)-containing species. In some embodiments, the F-containing species may be in a molecular form, such as a fluorinated gas. As shown in FIG. 1, the coating system 10 may include an inlet 28 through which a fluorinated gas may be introduced into the vacuum chamber 12, indicated by arrow A. The fluorinated gas may be introduced into the vacuum chamber 12 in a controlled manner. For example, a concentration of the fluorinated gas introduced into the vacuum chamber 12 may be controlled. In some embodiments, a flow controller or a leak valve may be used to control the introduction of the fluorinated gas into the vacuum chamber 12. In some other embodiments, an inert gas, such as argon (Ar), may be used as a carrier for introducing the fluorinated gas, where the fluorinated gas may be diluted in the inert gas before being introduced into the vacuum chamber 12. The fluorinated gas may create an F-rich atmosphere in the vacuum chamber 12. The fluorinated gas may have a concentration of 10 parts per billion (ppb) to 1000 parts per million (ppm) in the vacuum chamber 12. The fluorinated gas may include, but is not limited to, F₂, xenon difluoride (XeF₂), nitrogen trifluoride (NF₃), hydrogen fluoride (HF), carbon tetrafluoride (CF₄), sulfur hexafluoride (SF₆), or a combination thereof. The fluorinated gas may act as a dopant mixing with the gaseous target material 26 and deposited onto the at least one sample supported on the substrate holder 14 together with the gaseous target material 26. As such, an F-doped optical material may be generated on the at least one sample. The F-doped optical material may include a concentration of the doped F-containing species of less than 1000 parts per million (ppm) by volume of the optical material.

Doping the target material 22 with an additional F-containing species may help increase the concentration of F in the deposited optical material onto the at least one sample. Therefore, although fluorian vacancy may occur in the optical material when an optical component is under VUV and/or DUV radiation, the excess F atoms may sufficiently reoccupy the fluorian vacancy in the optical material, thereby reducing material defects under the VUV and/or DUV radiation. The excess F atoms may also attach to dangling bonds in the optical material to help repair the damaged optical material, thereby preventing the optical component from degradation and extending the lifetime of the optical component.

FIG. 2 depicts a schematic diagram of a coating system 40 according to a second embodiment of the present disclosure. In some embodiments, the coating system 40 may be used to deposit a first material onto a substrate to form an optical component. The first material may be deposited as a film layer onto the substrate. Thereafter, the coating system 40 may be used to deposit a second material onto the optical component. The second material may be deposited as a protective layer onto the optical component to protect the optical component from optical damage. The first and/or the second material may include an optical material, such as an F-containing optical material. The optical damage may be caused by VUV and/or DUV radiation. The optical component may be, but is not limited to, optical windows, beam splitters, mirrors, CCDs, detectors, or TDI CCDs. In some other embodiments, the coating system 40 may be used to deposit a material onto a bulk material of an optical component. The material may be deposited as a protective layer onto the optical component to protect the optical component from optical damage. The material may include an optical material, such as an F-containing optical material. The optical damage may be caused by VUV and/or DUV radiation. The optical component may be, but is not limited to, optical windows, beam splitters, mirrors, CCDs, detectors, or TDI CCDs.

The coating system 40 may be an electron beam (or e-beam) evaporation coating system. Referring to FIG. 2, the coating system 40 may include a vacuum chamber 42. The coating system 40 may further include a substrate holder 44 positioned at a first location within the vacuum chamber 42. The substrate holder 44 may include at least one recess 45. Each of the at least one recess 45 may support a sample thereon. The sample may be a substrate or a bulk material of an optical component. As such, at least one sample may be supported on the substrate holder 44 for deposition. The substrate holder 44 may also have a heating and temperature measurement capability, allowing a target material to be deposited onto the at least one sample at a specific temperature.

The coating system 40 may further include a rotating axis 46 which supports the substrate holder 44. The rotating axis 46 may include a motor (not shown) with configurable rotation speeds and configured to rotate the substrate holder 44 as the deposition of the target material takes place. The rotation of the substrate holder 44 during deposition may help achieve a uniform deposition of the target material on the at least one sample supported on the substrate holder 44.

The coating system 40 may also include an electron gun 48 configured to generate an electron beam 50 carrying high-energy electrons. The electron beam 50 may be directed to a target material 52 contained in a container 54. The container 54 is positioned at a second location within the vacuum chamber 44, for example, adjacent to the electron gun 48. The target material 52 may be an optical material to be deposited onto the at least one sample supported on the substrate holder 44. Upon being bombarded by the electron beam 50, the target material 52 may be melted, evaporated and transformed into a gaseous form 56. The gaseous atoms and/or molecules 56 of the target material 52 may then be condensed onto the at least one sample. A thickness of the deposited target material onto the at least one sample may be in a range of 1 nm to 1 μm. The target material 52 may be an F-containing optical material, including, but not limited to, MgF₂, LaF₂, LiF, BaF₂, AlF₃, GdF₃, LuF₃, or a combination thereof.

In some embodiments, when the at least one sample are substrates, a first target material may be deposited onto the substrates to form optical components. The first target material may be deposited as film layers onto the substrates. Thereafter, a second target material may be deposited onto the optical components. The second target material may be deposited as protective layers onto the optical components to protect the optical components from optical damage. The first and/or the second material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the first and second target materials deposited onto the at least one sample may be in a range of 1 nm to 1 μm.

In some other embodiments, when the at least one sample are bulk materials of optical components, a target material may be deposited onto the bulk materials of the optical components. The target material may be deposited as protective layers onto the optical components to protect the optical components from optical damage. The target material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the target material deposited onto the at least one sample may be in a range of 1 nm to 1 μm.

To further protect the deposited optical material from radiation damage, especially VUV and/or DUV radiation damage, the target material 52 may be doped with an additional F-containing species. In some embodiments, the F-containing species may be an atomic F species, such as F⁺ ions. As shown in FIG. 2, the coating system 40 may include an inlet 58 through which a fluorinated gas may be introduced into the vacuum chamber 42, indicated by arrow B. The fluorinated gas may be introduced into the vacuum chamber 42 in a controlled manner. For example, a concentration of the fluorinated gas introduced into the vacuum chamber 42 may be controlled. In some embodiments, a flow controller or a leak valve may be used to control the introduction of the fluorinated gas into the vacuum chamber 42. In some other embodiments, an inert gas, such as argon (Ar), may be used as a carrier for introducing the fluorinated gas, where the fluorinated gas may be diluted in the inert gas before being introduced into the vacuum chamber 42. The fluorinated gas may include, but is not limited to, F₂, XeF₂, NF₃, HF, CF₄, SF₆, or a combination thereof.

Referring to FIG. 2, an optical ionization source 60 may be used to ionize the fluorinated gas in order to generate the atomic F species, including F⁺ ions. In some embodiments, the optical ionization source 60 may be, but is not limited to, deuterium (D₂) lamps, laser-sustained plasmas or VUV and/or DUV light sources. The VUV and/or DUV light sources may be VUV and/or DUV lasers. In some other embodiments, the optical ionization source 60 may be an electron beam (i.e., other than 50) that can break down or dissociate bonds of the fluorinated gas to generate the atomic F species.

FIG. 2 shows that the optical ionization source 60 is positioned outside the vacuum chamber 42. When the optical ionization source 60 is positioned outside the vacuum chamber 42, the optical ionization source 60 may emit an optical energy to the fluorinated gas before the fluorinated gas is introduced into the vacuum chamber 42. The optical energy emitted by the optical ionization source 60 may thus ionize the fluorinated gas to generate the atomic F species, including F⁺ ions. Alternatively, the vacuum chamber 42 may include a window disposed thereon. The window may be a light-transparent window. The optical energy emitted by the optical ionization source 60 may pass through the window and ionize the fluorinated gas after the fluorinated gas is introduced into the vacuum chamber 42. In addition to being positioned outside the vacuum chamber 42, the optical ionization source 60 may also be positioned inside the vacuum chamber 42. For example, the optical ionization source 60 may be mounted on an inner surface of the vacuum chamber 42. When the optical ionization source 60 is positioned inside the vacuum chamber 42, the optical ionization source may also emit an optical energy to the fluorinated gas in the vacuum chamber 42 to ionize the fluorinated gas, thereby generating the atomic F species, including F⁺ ions.

As such, the atomic F species in the vacuum chamber 42 may create an F-rich atmosphere in the vacuum chamber 42. The atomic F species may have a concentration of 10 ppb to 1000 ppm in the vacuum chamber 42. The atomic F species may act as a dopant mixing with the gaseous target material 56 and deposited onto the at least one sample together with the gaseous target material 56. As such, an F-doped optical material may be generated on the at least one sample. The F-doped optical material may include a concentration of the doped F-containing species of less than 1000 ppm by volume of the optical material. Comparing with the scenario in FIG. 1, the atomic F species described in FIG. 2 may better mix with the gaseous target material 56, at least due to the smaller size of the atomic F species than that of the fluorinated gas.

Doping the target material 52 with an additional F-containing species may help increase the concentration of F in the deposited optical material onto the at least one sample. Therefore, although fluorian vacancy may occur in the optical material when an optical component is under VUV and/or DUV radiation, the excess F atoms may sufficiently reoccupy the fluorian vacancy in the optical material, thereby reducing material defects under the VUV and/or DUV radiation. The excess F atoms may also attach to dangling bonds in the optical material to help repair the damaged optical material, thereby preventing the optical component from degradation and extending the lifetime of the optical component.

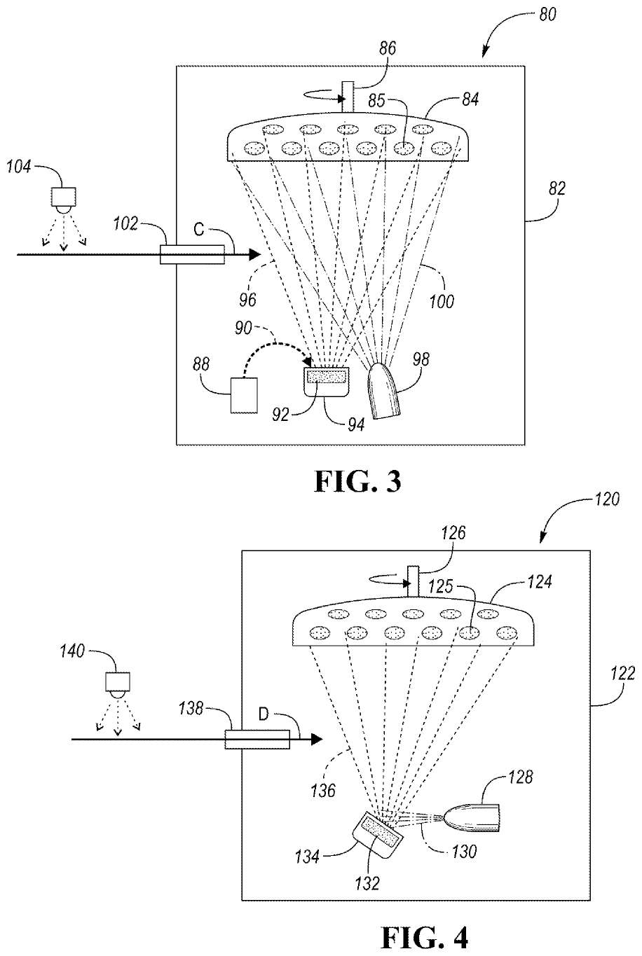

FIG. 3 depicts a schematic diagram of a coating system 80 according to a third embodiment of the present disclosure. In some embodiments, the coating system 80 may be used to deposit a first material onto a substrate to form an optical component. The first material may be deposited as a film layer onto the substrate. Thereafter, the coating system 80 may be used to deposit a second material onto the optical component. The second material may be deposited as a protective layer onto the optical component to protect the optical component from optical damage. The first and/or the second material may include an optical material, such as an F-containing optical material. The optical damage may be caused by VUV and/or DUV radiation. The optical component may be, but is not limited to, optical windows, beam splitters, mirrors, CCDs, detectors, or TDI CCDs. In some other embodiments, the coating system 80 may be used to deposit a material onto a bulk material of an optical component. The material may be deposited as a protective layer onto the optical component to protect the optical component from optical damage. The material may include an optical material, such as an F-containing optical material. The optical damage may be caused by VUV and/or DUV radiation. The optical component may be, but is not limited to, optical windows, beam splitters, mirrors, CCDs, detectors, or TDI CCDs.

The coating system 80 may be an ion assisted deposition (IAD) coating system. The IAD coating system is a variation of the electron beam evaporation coating system 10 and 40 illustrated in FIGS. 1 and 2, respectively. In addition to electron beam evaporation, the IAD coating system further employs an ion beam which is also directed to a substrate or a bulk material of an optical component. The ion beam can provide additional energy to the gaseous target material evaporated by the electron beam, promoting the formation of a denser and more uniform deposition of the optical material onto the substrate or the bulk material of the optical component. Moreover, the IAD coating system allows the deposited optical material to be pinhole free (e.g., no voids), producing high-quality deposition that is not only more environmentally stable (e.g., higher resistance to radiation damage) but also more durable. Furthermore, the ion beam in the IAD coating system may be used to clean the substrate or the bulk material of the optical component before deposition, where native oxides, water molecules and other contaminants adhering to the substrate or the bulk material of the optical component may be etched away using the ion beam. This allows for better deposition adhesion and prevents any impurities incorporating into the optical material during deposition.

Referring to FIG. 3, the coating system 80 may include a vacuum chamber 82. The coating system 80 may further include a substrate holder 84 positioned at a first location within the vacuum chamber 82. The substrate holder 84 may include at least one recess 85. Each of the at least one recess 85 may support a sample thereon. The sample may be a substrate or a bulk material of an optical component. As such, at least one sample may be supported on the substrate holder 84 for deposition. The substrate holder 84 may also have a heating and temperature measurement capability, allowing a target material to be deposited onto the at least one sample at a specific temperature.

The coating system 80 may further include a rotating axis 86 which supports the substrate holder 84. The rotating axis 86 may include a motor (not shown) with configurable rotation speeds and configured to rotate the substrate holder 84 as the deposition of an optical material takes place. The rotation of the substrate holder 84 during deposition may help achieve a uniform deposition of the target material on the at least one sample supported on the substrate holder 84.

The coating system 80 may further include an electron gun 88 configured to generate an electron beam 90 carrying high-energy electrons. The electron beam 90 may be directed to a target material 92 contained in a container 94. The container 94 is positioned at a second location within the vacuum chamber 82, for example, adjacent to the electron gun 88. The target material 92 may be an optical material to be deposited onto the at least one sample supported on the substrate holder 84. Upon being bombarded by the electron beam 90, the target material 92 may be melted, evaporated and transformed into a gaseous form 96. The gaseous atoms and/or molecules 96 of the target material 92 may then be condensed onto the at least one sample. A thickness of the deposited target material onto the at least one sample may be in a range of 1 nm to 1 μm. The target material 92 may be an F-containing optical material, including, but not limited to, MgF₂, LaF₂, LiF, BaF₂, AlF₃, GdF₃, LuF₃, or a combination thereof.

In some embodiments, when the at least one sample are substrates, a first target material may be deposited onto the substrates to form optical components. The first target material may be deposited as film layers onto the substrates. Thereafter, a second target material may be deposited onto the optical components. The second target material may be deposited as protective layers onto the optical components to protect the optical components from optical damage. The first and/or the second material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the first and second target materials deposited onto the at least one sample may be in a range of 1 nm to 1 μm.

In some other embodiments, when the at least one sample are bulk materials of optical components, a target material may be deposited onto the bulk materials of the optical components. The target material may be deposited as protective layers onto the optical components to protect the optical components from optical damage. The target material may include an optical material, such as an F-containing optical material. The F-containing optical material may be, but is not limited to, MgF₂, LaF₂, LiF, BaF₂, AlF₃, GdF₃, LuF₃, or a combination thereof. A thickness of the target material deposited onto the at least one sample may be in a range of 1 nm to 1 μm.

In addition to electron beam evaporation, the coating system 80 may further include an ion beam generator 98 configured to generate an ion beam 100 carrying high-energy ions upon a voltage is applied thereto. Before deposition (e.g., before the electron gun 88 is activated to generate the electron beam 90), the coating system 80 may use the ion beam generator 98 to clean the at least one sample supported on the substrate holder 84. Particularly, the ion beam generator 98 may generate a first ion beam which is directed to the at least one sample to clean the at least one sample, where native oxides, water molecules and other contaminants adhering to the at least one sample may be etched away using the first ion beam. In some embodiments, the first ion beam may include inert gas ions. The inert gas ions may be, but are not limited to, Ar⁺ ions, neon ions (Ne⁺), krypton ions (Kr⁺), or xenon ions (Xe⁺). As shown in FIG. 3, the vacuum chamber 82 of the coating system 80 may further include an inlet 102 through which an inert gas, such as Ar, may be introduced into the vacuum chamber 82, indicated by arrow C, before deposition.

After cleaning the at least one sample using the ion beam generator 98, the electron gun 88 may be activated to generate the electron beam 90 to bombard the target material 92 contained in the container 94 for deposition. The ion beam generator 98 may then generate a second ion beam which is directed to the at least one sample supported on the substrate holder 84. The second ion beam may provide additional energy to the gaseous target material 96 evaporated by the electron beam 90, promoting the formation of a denser and more uniform deposition of the optical material onto the at least one sample. In some embodiments, the second ion beam may include F⁺ ions. The F⁺ ions may act as a dopant mixing with the gaseous target material 96 and deposited onto the at least one sample together with the gaseous target material 96. As such, an F-doped optical material may be generated onto the at least one sample. The F-doped optical material may include a concentration of the doped F-containing species of less than 1000 ppm by volume of the optical material.

In some embodiments, to further increase the concentration of atomic F species, such as F⁺ ions, in the vacuum chamber 82, a fluorinated gas may be introduced into the vacuum chamber 82 via the inlet 102 during deposition. The fluorinated gas may be introduced into the vacuum chamber 82 in a controlled manner. For example, a concentration of the fluorinated gas introduced into the vacuum chamber 82 may be controlled. In some embodiments, a flow controller or a leak valve may be used to control the introduction of the fluorinated gas into the vacuum chamber 82. In some other embodiments, an inert gas, such as Ar, may be used as a carrier for introducing the fluorinated gas, where the fluorinated gas may be diluted in the inert gas before being introduced into the vacuum chamber 82. The fluorinated gas may include, but is not limited to, F₂, XeF₂, NF₃, HF, CF₄, SF₆, or a combination thereof. Referring to FIG. 3, an optical ionization source 104 may be used to ionize the fluorinated gas in order to generate the atomic F species. In some embodiments, the optical ionization source 106 may be, but is not limited to, deuterium (D₂) lamps, laser-sustained plasmas or VUV and/or DUV light sources. The VUV and/or DUV light sources may be VUV and/or DUV lasers. In some other embodiments, the optical ionization source 106 may be an electron beam (i.e., other than 90) that can break down or dissociate bonds of the fluorinated gas to generate the atomic F species, such as F⁺ ions. The atomic F species may have a concentration of 10 ppb to 1000 ppm in the vacuum chamber 82.

FIG. 3 shows that the optical ionization source 106 is positioned outside the vacuum chamber 82. When the optical ionization source 106 is positioned outside the vacuum chamber 82, the optical ionization source 106 may emit an optical energy to the fluorinated gas before the fluorinated gas is introduced into the vacuum chamber 82. The optical energy emitted by the optical ionization source 106 may thus ionize the fluorinated gas to generate the atomic F species, such as F⁺ ions. Alternatively, the vacuum chamber 82 may include a window disposed thereon. The window may be a light-transparent window. The optical energy emitted by the optical ionization source 106 may pass through the window and ionize the fluorinated gas after the fluorinated gas is introduced into the vacuum chamber 82. In addition to being positioned outside the vacuum chamber 82, the optical ionization source 106 may also be positioned inside the vacuum chamber 82. For example, the optical ionization source 106 may be mounted on an inner surface of the vacuum chamber 82. When the optical ionization source 106 is positioned inside the vacuum chamber 82, the optical ionization source may also emit an optical energy to the fluorinated gas in the vacuum chamber 82 to ionize the fluorinated gas, thereby generating the atomic F species, such as F⁺ ions.

Doping the target material 92 with an additional F-containing species may help increase the concentration of F in the deposited optical material onto the at least one sample. Therefore, although fluorian vacancy may occur in the optical material when an optical component is under VUV and/or DUV radiation, the excess F atoms may sufficiently reoccupy the fluorian vacancy in the optical material, thereby reducing material defects under the VUV and/or DUV radiation. The excess F atoms may also attach to dangling bonds in the optical material to help repair the damaged optical material, thereby preventing the optical component from degradation and extending the lifetime of the optical component.

A method of depositing a material onto at least one sample using an IAD coating system is described. The IAD coating system may be the coating system as described in FIG. 3. The material may be an optical material, for example, an F-containing optical material. The F-containing optical material may be, but is not limited to, MgF₂, LaF₂, LiF, BaF₂, AlF₃, GdF₃, LuF₃, or a combination thereof. A thickness of the material deposited onto the at least one sample may be in a range of 1 nm to 1 μm. The method may include a cleaning stage and a deposition stage. During the cleaning stage, the method may include generating a first ion beam by an ion beam generator of the coating system. The first ion beam may be directed to the at least one sample supported on the substrate holder to clean the at least one sample. The first ion beam may include inert gas ions. The inert gas ions may be, but are not limited to, Ar⁺ ions, Ne⁺ ions, Kr⁺ ions, or Xe⁺ ions. The method may also include introducing Ar gas into the coating system while cleaning the at least one sample. After cleaning, the deposition stage of the method may include activating an electron gun of the coating system. The electron gun may generate an electron beam which bombards the material. The method may further include generating a second ion beam by the ion beam generator. The second ion beam may be directed to the at least one sample. The second ion beam may include F⁺ ions. The second ion beam may provide additional energy to the gaseous material evaporated by the electron beam. The F⁺ ions may act as a dopant mixing with the gaseous material and deposited onto the at least one sample together with the gaseous material. As such, an F-doped optical material may be generated onto the at least one sample. Additionally, the method may include introducing a fluorinated gas into the coating system. The fluorinated gas may be ionized by an optical ionization source to generate more F⁺ ions in the coating system, thereby creating an F-rich environment in the coating system.

FIG. 4 depicts a schematic diagram of a coating system 120 according to a fourth embodiment of the present disclosure. In some embodiments, the coating system 120 may be used to deposit a first material onto a substrate to form an optical component. The first material may be deposited as a film layer onto the substrate. Thereafter, the coating system 120 may be used to deposit a second material onto the optical component. The second material may be deposited as a protective layer onto the optical component to protect the optical component from optical damage. The first and/or the second material may include an optical material, such as an F-containing optical material. The optical damage may be caused by VUV and/or DUV radiation. The optical component may be, but is not limited to, optical windows, beam splitters, mirrors, CCDs, detectors, or TDI CCDs. In some other embodiments, the coating system 120 may be used to deposit a material onto a bulk material of an optical component. The material may be deposited as a protective layer onto the optical component to protect the optical component from optical damage. The material may include an optical material, such as an F-containing optical material. The optical damage may be caused by VUV and/or DUV radiation. The optical component may be, but is not limited to, optical windows, beam splitters, mirrors, CCDs, detectors, or TDI CCDs.

The coating system 120 may be an ion beam sputtering (IBS) coating system. The IBS coating system employs a variable-energy ion beam which is directed to a target material. The target material may be a coating material to be deposited onto a substrate or a bulk material of an optical component. The ion beam bombards the target material with high kinetic energy (e.g., about 1000 eV). Upon being bombarded by the ion beam, atoms from the target material are sputtered and directed toward the substrate or the bulk material and condensed onto the substrate or the bulk material. The IBS coating system can provide a robust coating with excellent thickness control, and can ensure a coating with low absorption and scatter, low surface roughness, and minimal wavelength shift.

Referring to FIG. 4, the coating system 120 may include a vacuum chamber 122. The coating system 120 may further include a substrate holder 124 positioned at a first location within the vacuum chamber 122. The substrate holder 124 may include at least one recess 125. Each of the at least one recess 125 may support a sample thereon. The sample may be a substrate or a bulk material of an optical component. As such, at least one sample may be supported on the substrate holder 124 for deposition. The substrate holder 124 may also have a heating and temperature measurement capability, allowing a target material to be deposited onto the at least one sample at a specific temperature.

The coating system 120 may further include a rotating axis 126 which supports the substrate holder 124. The rotating axis 126 may include a motor (not shown) with configurable rotation speeds and configured to rotate the substrate holder 124 as the deposition of a target material takes place. The rotation of the substrate holder 124 during deposition may help achieve a uniform deposition of the target material on the at least one sample.

The coating system 120 may also include an ion beam generator 128 configured to generate an ion beam 130 carrying high-energy ions. The ion beam generator 128 may be rotatable. For example, the ion beam generator 128 may be rotated in a first direction to direct to the at least one sample supported on the substrate holder 124 or may be rotated in a second direction to direct to a target material 132 contained in a container 134 of the coating system 120. The container 134 is positioned at a second location within the vacuum chamber 124, for example, adjacent to the ion beam generator 128. The target material 132 may be a coating material to be deposited onto the at least one sample supported on the substrate holder 124. Before deposition of the target material 132 onto the at least one sample, the coating system 120 may use the ion beam generator 128 to clean the at least one sample. Particularly, the ion beam generator 128 may generate a first ion beam which is directed to the at least one sample to clean the at least one sample, where native oxides, water molecules and other contaminants adhering to the at least one sample may be etched away using the first ion beam. In some embodiments, the first ion beam may include inert gas ions. The inert gas ions may be, but are not limited to, Ar⁺ ions, Ne⁺ ions, Kr⁺ ions, or Xe⁺ ions. As shown in FIG. 4, the coating system 120 may further include an inlet 138 through which an inert gas, such as Ar, may be introduced into the vacuum chamber 122, indicated by arrow D, before deposition.

After cleaning the at least one sample using the ion beam generator 128, the ion beam generator 128 may be rotated and generate a second ion beam which is directed to the target material 132. Upon being bombarded by the second ion beam, the target material 132 may be sputtered and directed toward the at least one sample supported on the substrate holder 124 and condensed onto the at least one sample. The target material 132 may be an F-containing optical material, including, but not limited to, MgF₂, LaF₂, LiF, BaF₂, AlF₃, GdF₃, LuF₃, or a combination thereof. In some embodiments, the second ion beam may include F⁺ ions. The F⁺ ions may act as a dopant mixing with the sputtered target material 136 and deposited onto the at least one sample together with the sputtered target material 136. As such, an F-doped optical material may be generated onto the at least one sample. A thickness of the target material deposited onto the at least one sample may be in a range of 1 nm to 1 μm. The F-doped optical material may include a concentration of the doped F-containing species of less than 1000 ppm by volume of the optical material.

In some embodiments, to further increase the concentration of atomic F species, such as F⁺ ions, in the vacuum chamber 122, a fluorinated gas may be introduced into the vacuum chamber 122 via the inlet 138 during deposition. The fluorinated gas may be introduced into the vacuum chamber 122 in a controlled manner. For example, a concentration of the fluorinated gas introduced into the vacuum chamber 122 may be controlled. In some embodiments, a flow controller or a leak valve may be used to control the introduction of the fluorinated gas into the vacuum chamber 122. In some other embodiments, an inert gas, such as Ar, may be used as a carrier for introducing the fluorinated gas, where the fluorinated gas may be diluted in the inert gas before being introduced into the vacuum chamber 122. The fluorinated gas may include, but is not limited to, F₂, XeF₂, NF₃, HF, CF₄, SF₆, or a combination thereof. Referring to FIG. 4, an optical ionization source 140 may be used to ionize the fluorinated gas in order to generate the atomic F species. In some embodiments, the optical ionization source 140 may be, but is not limited to, deuterium (D₂) lamps, laser-sustained plasmas or VUV and/or DUV light sources. The VUV and/or DUV light sources may be VUV and/or DUV lasers. In some other embodiments, the optical ionization source 140 may be an electron beam that can break down or dissociate bonds of the fluorinated gas to generate the atomic F species, such as F⁺ ions. The atomic F species may have a concentration of 10 ppb to 1000 ppm in the vacuum chamber 122.

FIG. 4 shows that the optical ionization source 140 is positioned outside the vacuum chamber 122. When the optical ionization source 140 is positioned outside the vacuum chamber 122, the optical ionization source 140 may emit an optical energy to the fluorinated gas before the fluorinated gas is introduced into the vacuum chamber 122. The optical energy emitted by the optical ionization source 140 may thus ionize the fluorinated gas to generate the atomic F species, such as F⁺ ions. Alternatively, the vacuum chamber 122 may include a window disposed thereon. The window may be a light-transparent window. The optical energy emitted by the optical ionization source 140 may pass through the window and ionize the fluorinated gas after the fluorinated gas is introduced into the vacuum chamber 122. In addition to being positioned outside the vacuum chamber 122, the optical ionization source 140 may also be positioned inside the vacuum chamber 122. For example, the optical ionization source 140 may be mounted on an inner surface of the vacuum chamber 122. When the optical ionization source 140 is positioned inside the vacuum chamber 122, the optical ionization source may also emit an optical energy to the fluorinated gas in the vacuum chamber 122 to ionize the fluorinated gas, thereby generating the atomic F species, such as F⁺ ions.

Doping the target material 132 with an additional F-containing species may help increase the concentration of F in the deposited optical material onto the at least one sample. Therefore, although fluorian vacancy may occur in the optical material when an optical component is under VUV and/or DUV radiation, the excess F atoms may sufficiently reoccupy the fluorian vacancy in the optical material, thereby reducing material defects under the VUV and/or DUV radiation. The excess F atoms may also attach to dangling bonds in the optical material to help repair the damaged optical material, thereby preventing the optical component from degradation and extending the lifetime of the optical component.

A method of depositing a material onto at least one sample using an IBS coating system is described. The IBS coating system may be the coating system as described in FIG. 4. The material may be an optical material, for example, an F-containing optical material. The F-containing optical material may be, but is not limited to, MgF₂, LaF₂, LiF, BaF₂, AlF₃, GdF₃, LuF₃, or a combination thereof. A thickness of the material deposited onto the at least one sample may be in a range of 1 nm to 1 μm. The method may include a cleaning stage and a deposition stage. During the cleaning stage, the method may include generating a first ion beam by an ion beam generator of the coating system. The ion beam generator may be rotated in a first direction such that the first ion beam is directed to the at least one sample supported on the substrate holder to clean the at least one sample. The first ion beam may include inert gas ions. The inert gas ions may be, but are not limited to, Ar⁺ ions, Ne⁺ ions, Kr⁺ ions, or Xe⁺ ions. The method may also include introducing Ar gas into the coating system while cleaning the at least one sample. After cleaning, the deposition stage of the method may include generating a second ion beam by the ion beam generator. The ion beam generator may be rotated in a second direction such that the second ion beam is directed to the material. The second ion beam may include F⁺ ions. The F⁺ ions may act as a dopant mixing with the gaseous material and deposited onto the at least one sample together with the gaseous material. As such, an F-doped optical material may be generated onto the at least one sample. Additionally, the method may include introducing a fluorinated gas into the coating system. The fluorinated gas may be ionized by an optical ionization source to generate more F⁺ ions in the coating system, thereby creating an F-rich environment in the coating system.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A coating system for depositing an optical material onto at least one sample, where the at least one sample is a substrate or a bulk material of an optical component, the coating system comprising:
a vacuum chamber;
a substrate holder positioned at a first location within the vacuum chamber, the substrate holder having at least one recess to support the at least one sample;
a rotating axis supporting the substrate holder and configured to rotate the substrate holder as the optical material is deposited onto the at least one sample;
a container positioned at a second location within the vacuum chamber, the container containing a target material to be deposited as the optical material onto the at least one sample, the target material including an F-containing optical material;
an electron gun positioned adjacent to the container and configured to generate an electron beam, the electron beam being directed to the target material to melt and evaporate the target material in a gaseous form which is then condensed as the optical material onto the at least one sample; and
an inlet disposed on the vacuum chamber and through which an F-containing species is introduced into the vacuum chamber, the F-containing species being mixed with the target material in the gaseous form and deposited onto the at least one sample with the target material in the gaseous form.

2. The coating system of claim 1, wherein the F-containing optical material is selected from the group consisting of MgF₂, LaF₂, LiF, BaF₂, AlF₃, GdF₃, LuF₃, and a combination thereof.

3. The coating system of claim 1, wherein the F-containing species is a fluorinated gas.

4. The coating system of claim 3, wherein the fluorinated gas is selected from the group consisting of F₂, XeF₂, NF₃, HF, CF₄, SF₆, and a combination thereof.

5. The coating system of claim 1, wherein the F-containing species is an F⁺ ion.

6. The coating system of claim 1, wherein the optical material has a thickness in a range of 1 nm to 1 μm.

7. The coating system of claim 1, wherein the optical material includes a concentration of the F-containing species of less than 1000 ppm by volume of the optical material.

8. The coating system of claim 1, further comprising an ion beam generator positioned adjacent to the container and configured to generate a first ion beam containing inert gas ions to clean the at least one sample and to generate a second ion beam containing fluorine ions, the second ion beam being directed to the at least one sample during deposition and providing additional energy to the target material in the gaseous form to promote deposition of the target material onto the at least one sample.

9. A coating system for depositing an optical material onto at least one sample, where the at least one sample is a substrate or a bulk material, the coating system comprising:
a vacuum chamber;
a substrate holder positioned at a first location within the vacuum chamber, the substrate holder having at least one recess to support the at least one sample;
a rotating axis supporting the substrate holder and configured to rotate the substrate holder as the optical material is deposited onto the at least one sample;
a container positioned at a second location within the vacuum chamber, the container containing a target material to be deposited as the optical material onto the at least one sample, the target material including an F-containing optical material;
an ion beam generator positioned adjacent to the container and configured to rotate in a first direction to direct to the at least one sample and to generate a first ion beam containing inert gas ions to clean the at least one sample, the ion beam generator also being configured to rotate in a second direction to direct to the target material in the container during deposition and to generate a second ion beam containing fluorine ions to sputter the target material for depositing the target material onto the at least one sample; and
an inlet disposed on the vacuum chamber and through which an F-containing species is introduced into the vacuum chamber, the F-containing species being mixed with the target material and deposited onto the at least one sample with the target material.

10. The coating system of claim 9, wherein the F-containing optical material is selected from the group consisting of MgF₂, LaF₂, LiF, BaF₂, AlF₃, GdF₃, LuF₃, and a combination thereof.

11. The coating system of claim 9, wherein the F-containing species is a fluorinated gas.

12. The coating system of claim 11, wherein the fluorinated gas is selected from the group consisting of F₂, XeF₂, NF₃, HF, CF₄, SF₆, and a combination thereof.

13. The coating system of claim 9, wherein the F-containing species is an F⁺ ion.

14. An optical component comprising:
an optical material including a fluorine (F)-containing optical material doped with an F-containing species different from the F-containing optical material.

15. The optical component of claim 14, wherein the F-containing optical material is selected from the group consisting of magnesium fluoride (MgF₂), lanthanum fluoride (LaF₂), lithium fluoride (LiF), barium fluoride (BaF₂), aluminum fluoride (AlF₃), gadolinium fluoride (GdF₃), lutetium fluoride (LuF₃), and a combination thereof.

16. The optical component of claim 14, wherein the F-containing species is a fluorinated gas.

17. The optical component of claim 16, wherein the fluorinated gas is selected from the group consisting of fluorine (F₂), xenon difluoride (XeF₂), nitrogen trifluoride (NF₃), hydrogen fluoride (HF), carbon tetrafluoride (CF₄), sulfur hexafluoride (SF₆), and a combination thereof.

18. The optical component of claim 14, wherein the F-containing species is an F⁺ ion.

19. The optical component of claim 14, wherein the optical material has a thickness of 1 nm to 1 μm.

20. The optical component of claim 14, wherein the optical material includes a concentration of the F-containing species of less than 1000 ppm by volume of the optical material.
